(19) United States
(12) Patent Application Publication
(10) Pub. No.: US 2026/0101553 A1
(43) Pub. Date: Apr. 9, 2026

(54) SEMICONDUCTOR DEVICES WITH LENGTH-GRADED CHANNEL

(71) Applicant: Wolfspeed, Inc., Durham, NC (US)

(72) Inventors: Rahul R. Potera, Apex, NC (US); Andreas Scholze, Cary, NC (US); Sei-Hyung Ryu, Cary, NC (US)

(21) Appl. No.: 18/910,403

(22) Filed: Oct. 9, 2024

(51) Int. Cl. H01L 29/10; H01L 29/66; H01L 29/78

(52) U.S. Cl. CPC H10D 62/307; H10D 30/0291; H10D 30/66

(57) ABSTRACT

A vertical semiconductor device includes a drift layer, a mesa on the drift layer, and a trench adjacent to the mesa. The mesa includes a mesa sidewall, a channel layer and a source layer on the channel layer. The channel layer is between the source layer and the drift layer. A sidewall gate region in the mesa adjacent the mesa sidewall and a sidewall channel region is in the channel layer adjacent the sidewall gate region. The channel layer is doped with first conductivity type dopants and has a first doping concentration. The sidewall channel region is doped with first conductivity type dopants and has a second doping concentration that is greater than the first doping concentration. The sidewall gate region extends deeper toward the drift layer than the sidewall channel region.

### TECHNICAL FIELD

The present disclosure relates to semiconductor devices and, more particularly, to vertical power semiconductor devices.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate metal layers, and one or more gate buses and/or gate metal layers that electrically connect the gate pad to the gate metal layers. The gate metal layers are disposed adjacent the respective channel regions. Power JFETs are typically normally-on devices, meaning that a JFET conducts current when a voltage of 0 volts is applied to the gate. When a sufficiently negative voltage (referred to as the threshold voltage, VT) is applied to the gate structure, the channel is pinched off and the JFET ceases to conduct current.

### SUMMARY

A vertical semiconductor device according to some embodiments includes a drift layer, a mesa on the drift layer, and a trench adjacent to the mesa. The mesa includes a mesa sidewall, a channel layer and a source layer on the channel layer. The channel layer is between the source layer and the drift layer. A sidewall gate region in the mesa adjacent the mesa sidewall and a sidewall channel region is in the channel layer adjacent the sidewall gate region. The channel layer is doped with first conductivity type dopants and has a first doping concentration. The sidewall channel region is doped with first conductivity type dopants and has a second doping concentration that is greater than the first doping concentration. The sidewall gate region extends deeper toward the drift layer than the sidewall channel region.

The sidewall channel region may have a graded doping profile in a vertical direction. For example, the sidewall channel region may have a step graded doping profile or a continuously graded doping profile.

In some embodiments, the channel layer has a first length in a vertical direction and wherein the sidewall channel layer has a second length in the vertical direction that is less than the first length.

In some embodiments, the first doping concentration is about 1E16 to 1E17 cm-3 and the second doping concentration is about 1E17 to 1E18 cm-3. For example, the first doping concentration may be less than about 1E17 cm-3 and the second doping concentration may be greater than about 1E17 cm-3.

The mesa may have a width of about 1 micron to 1.5 microns and the trench has a width of about 1 micron to 1.5 microns. In some embodiments, the mesa has a width of about 1.2 microns to 1.4 microns and the trench has a width of about 1.2 microns to 1.4 microns. The trench may have an aspect ratio of about 1.5 to 2.

A method of forming a vertical semiconductor device according to some embodiments includes forming a mesa in a semiconductor layer and a trench adjacent to the mesa, wherein the mesa includes a mesa sidewall, the mesa including a channel layer and a source layer on the channel layer, wherein the semiconductor layer, the channel layer and the source layer have a first conductivity type. The method further includes implanting second conductivity type dopant ions into a sidewall of the mesa at a first implant angle to form a sidewall gate region in the mesa, and implanting first conductivity type dopant ions into the sidewall of the mesa at a second implant angle to form a sidewall channel region in the channel layer adjacent to the sidewall gate region. The first implant angle is different from the second implant angle.

In some embodiments, the first implant angle is greater than the second implant angle, wherein the first and second implant angles are measured relative to a normal direction.

In some embodiments, the sidewall channel region has a smaller doping concentration in a lower region of the mesa and a larger doping concentration in an upper region of the mesa.

The channel layer and/or the sidewall gate region may extend deeper in the mesa than the sidewall channel region.

The sidewall channel region may have a graded doping profile in a vertical direction, such as a step graded doping profile or a continuously graded doping profile.

The first implant angle may be less than 30 degrees and the second implant angle is greater than 30 degrees.

The trench may have an aspect ratio of about 1.5 to 2.

A vertical semiconductor device according to some embodiments includes a drift layer, a mesa on the drift layer, and a trench adjacent to the mesa, wherein the mesa includes a mesa sidewall, the mesa including a channel layer and a source layer on the channel layer. The device further includes a sidewall channel region in the channel layer, wherein the sidewall channel region is doped with first conductivity type dopants and has a first doping concentration, wherein the sidewall channel region has a smaller doping concentration in a lower region near the drift layer and a larger doping concentration in an upper region away from the drift layer.

A vertical semiconductor device according to some embodiments includes a drift layer, wherein the drift layer is doped with dopant atoms having a first conductivity type at a first doping concentration, a mesa on the drift layer, and a trench adjacent to the mesa, wherein the mesa includes a mesa sidewall, the mesa including a channel layer and a source layer on the channel layer, wherein the channel layer is between the source layer and the drift layer, a sidewall gate region in the mesa adjacent the mesa sidewall, and a sidewall channel region in the channel layer adjacent the sidewall gate region. The sidewall channel region is doped with first conductivity type dopants and has a second doping concentration that is greater than the first doping concentration. The sidewall channel region has a smaller doping concentration in a lower region near the drift layer and a larger doping concentration in an upper region away from the drift layer.

A method of forming a vertical semiconductor device according to some embodiments includes forming a plurality of mesas in a semiconductor layer and a plurality of trenches adjacent to respective ones of the mesas, wherein each of the plurality of mesas includes a mesa sidewall, a channel layer and a source layer on the channel layer, wherein the semiconductor layer, the channel layer and the source layer have a first conductivity type, and implanting first conductivity type dopant ions into the sidewalls of the mesas at an implant angle to form sidewall channel regions in the channel layer. A first sidewall gate region extends to a first depth in a first one of the mesas that is less than a depth of the channel layer. A second one of the mesas has a different width than the first one of the mesas due to a process variation, and a second sidewall gate region extends to a second depth in the second one of the mesas that is different from the first depth.

The implant angle may be a first implant angle, and the method may further include implanting second conductivity type dopant ions into the sidewalls of the mesa at a second implant angle that is less than the first implant angle to form the sidewall gate regions in the mesas.

The sidewall gate regions may extend deeper in the mesa than the first sidewall channel region.

The sidewall channel region may have a smaller doping concentration in a lower region of the mesa and a larger doping concentration in an upper region of the mesa.

The channel layer may extend deeper in the mesa than the sidewall channel regions.

The sidewall channel regions have a graded doping profile in a vertical direction, such as a step graded doping profile or a continuously graded doping profile.

### BRIEF DESCRIPTION OF DRAWINGS

FIGS. 1 and 2 illustrate a cell of a vertical JFET semiconductor device.

FIGS. 3A, 3B and 3C are cross-sectional views of JFET structures according to some embodiments.

FIGS. 4A, 4B and 4C are cross-sectional views that illustrate some operations for forming JFET structures according to some embodiments.

FIGS. 5A, 5B and 5C are cross-sectional views that illustrate some operations for forming JFET structures according to some embodiments.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art. Like reference numbers refer to like elements throughout the description.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

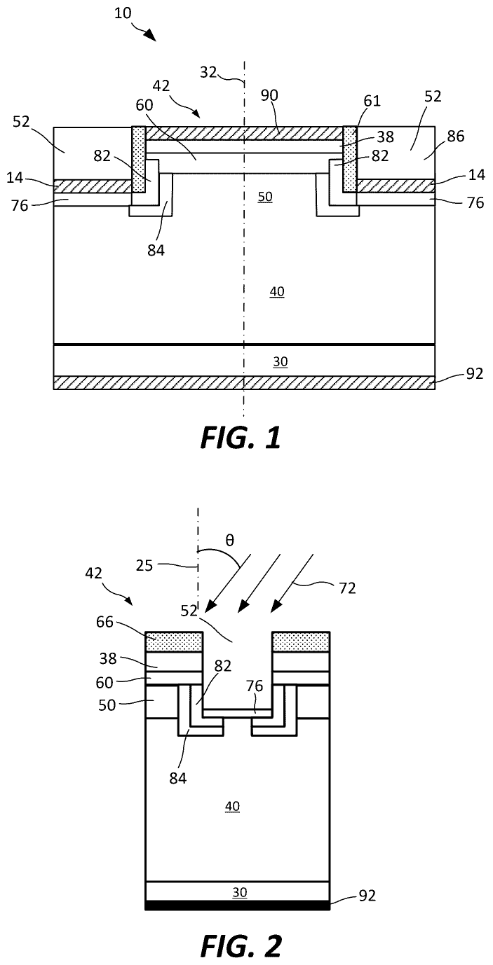

An n-channel vertical JFET structure 10 is shown in FIG. 1. The vertical JFET structure 1 includes an n+ substrate 30 on which an n− drift layer 40 is formed. The substrate 30, drift layer 40 and other layers may comprise silicon carbide single crystal layers having a polytype such as 2H, 4H, 6H, 3C or 15R.

An n-type channel region 50 is on the drift layer 40, and an n+ source layer 60 is on the channel region 50.

An n++ source contact layer 38 is on the n+ source layer 60. A drain ohmic contact 92 is on the substrate 30, and a source metal layer 90 is on the source contact layer 38. The channel region 50, source layer 60 and source contact layer 38 are provided as part of a mesa stripe 42 above the drift layer 40. Trenches 52 are formed in the structure 10 adjacent the mesa stripe 42.

A p+ gate region 82 is provided as part of the mesa stripe 42 adjacent the channel region 50. An n+ implanted sidewall channel region 84 is formed in the channel region 50 adjacent the p+ gate region 82. A p++ gate contact region 76 is provided adjacent the gate region 82, and a gate ohmic contact, or gate finger, 14 is formed on the gate contact region 76 in the trenches 52 on opposite sides of the mesa stripe 42.

In some embodiments, the sidewall channel region 84 has a doping concentration of about 1E17 cm-3 or greater, such as between about 1E17 cm-3 and 1E19 cm-3. In some embodiments, the sidewall channel region 84 has a doping concentration of between about 3E17 cm-3 and 5E18 cm-3. In some embodiments, the sidewall channel region 84 has a doping concentration of about 1E18 cm-3.

In some embodiments, the channel layer 50 has a doping concentration of between about 5E15 cm-3 and 1E17 cm-3. In some embodiments, the channel layer 50 has a doping concentration of about 5E16 cm-3 or less, such as between about 5E15 cm-3 and 5E16 cm-3. In some embodiments, the channel layer 50 has a doping concentration of about 1.5E16 cm-3.

In some embodiments, the sidewall channel region 84 has a doping concentration at least about 10 times greater than a doping concentration of the channel layer 50, and in some cases at least about 100 times greater.

To form the gate finger 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 86 is formed in the trenches 52 on the gate finger 14 and the gate contact region 76. The insulation layer 86 may be formed from silicon oxide. Oxide/nitride spacer layers 61 are provided on sidewalls of the mesa stripe 42.

The vertical JFET unit cell structure 10 is symmetrical about the axis 32 and includes two gate regions 82 as part of the mesa stripe 42 on opposite sides of the channel region 50.

The channel of the vertical JFET structure 10 is formed within the mesa stripe 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length (i.e., the distance carriers travel through the channel from the source to the drain) is chosen based on a trade-off between low on-resistance in the on-state and resistance to drain-induced barrier lowering (DIBL) in the off-state. A p-channel JFET may have a similar structure, but the conductivity types are reversed from those shown in FIG. 1.

FIG. 2 illustrates the formation of the p+ sidewall gate regions 82 and the n+ sidewall channel regions 84. In particular, the p+ sidewall gate regions 82 and the n+ sidewall channel regions 84 are formed through the use of angled implants 72 after formation of the trenches 52 and mesas 42 in the structure. An implant mask 66 is formed on the mesas 42, and n-type dopants 72 are implanted at an implant angle θ that is angled relative to a normal direction 28 that is perpendicular to the substrate 30. The substrate 30 is rotated during implantation so that both sidewalls of the trench 52 are implanted. The p+ sidewall gate regions 82 are implanted using p-type dopant ions at a lower implant energy so that the n+ sidewall channel regions 84 extend deeper into both the channel region 50 and the drift layer 40 than the p+sidewall gate regions 82.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) V_{GS} is applied to the gate regions 82. When no voltage is applied to the gate region 82, charge carriers can flow freely from the source layer 60 through the channel region 50 and the drift layer 40 to the substrate 30. That is, the device 10 is normally ON, meaning that current can flow from the source contact 90 to the drain contact 92 through the channel 50 when no voltage is applied to the gate contact 14.

When a negative voltage is applied to the gate contact 14, depletion regions form at the PN junctions between the gate regions 82 and the sidewall channel regions 84 on both sides of the mesa 42. As the voltage applied to the gate becomes more negative, the depletion regions expands into the channel layer 50, reducing or preventing current flow between the source 90 and drain 92 contacts and eventually pinching off the channel entirely, blocking the flow of current.

The gate voltage primarily controls the barrier to the flow of charge carriers from the source 90 to the drain 92. However, as the channel length of the device is reduced short channel effects such as DIBL become significant. In particular, when a high voltage is applied to the drain of the device while it is in the OFF state, a strong electric field is created that penetrates into the channel. This can lower the barrier to charge flow, causing the device to turn on at a less negative gate voltage. For example, if the threshold voltage VT of a device −20V, DIBL can cause the device to turn on at a voltage greater than −20 V. This means that the device may turn on at a different gate voltage than expected or even when the gate voltage is intended to keep it off.

DIBL may lead to increased leakage current when the device is supposed to be in the OFF state. It may also reduce the control the gate has over the channel, potentially affecting the performance and reliability of the device.

It is generally desirable to keep DIBL to a minimum to keep the off-state gate to source voltage (Vgs) of the device from being too low, for example −20V. However, as manufacturing process variations result in variation of the mesa width, DIBL also changes. Wider mesas tend to exhibit more DIBL is also the most extreme while the specific on resistance (Rsp) is lowest. Narrower mesas tend to have lower DIBL but higher Rsp. It is desirable to reduce the sensitivity of DIBL and Rsp to mesa width.

Some embodiments provide a SIT or JFET structure in which the sidewall channel region has a doping concentration that is graded along the length of the channel. This may reduce the impact of mesa width variation on DIBL and Rsp.

In particular, some embodiments provide a device having step-graded concentration in the sidewall channel, with a higher dopant concentration in an upper portion of the channel nearest the source region and a lower donor concentration towards the drain-end of the channel. The boundary between lower and higher concentration regions of the channel may be engineered to shift further towards the drain-end of the channel when mesa width of the device narrows, and to shift away from the drain-end of the channel when mesa width of the device widens as a result of normal process variations.

Normally, as the mesa width narrows and the trench width increases for a given device pitch, the drain-source ON resistance (RDSON) of the device increases. In some embodiments, a boundary shift of the sidewall channel doping towards the drain-end as the mesa width narrows results in a more conductive channel, thereby reducing the maximum RDSON of the device.

Conversely, as the mesa widens and the trench becomes more narrow, DIBL typically increases. In some embodiments, a boundary shift of the sidewall channel doping away from drain-end results in a less conductive channel, reducing DIBL. In this manner, a device according to some embodiments may have reduced maximum RDSON and DIBL in the device across process variations.

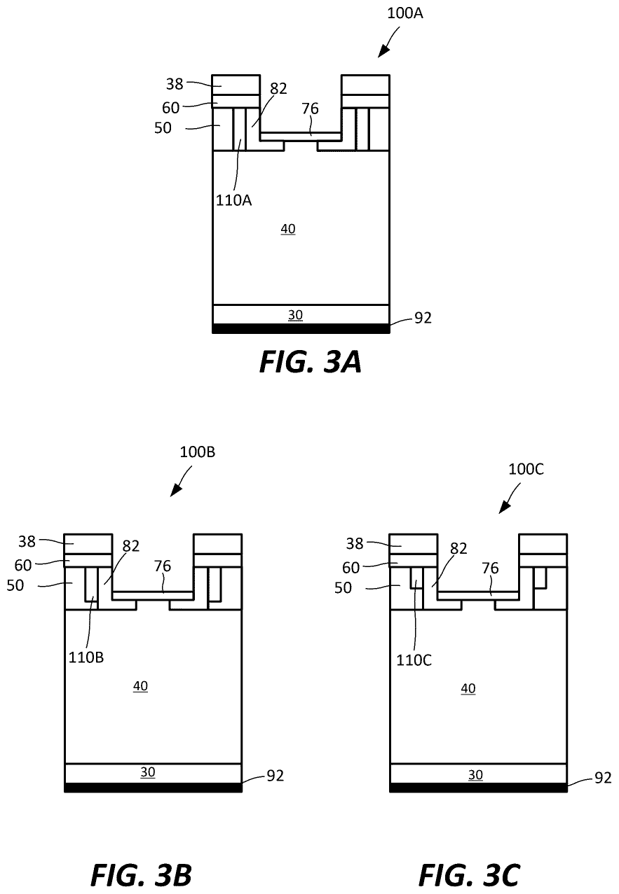

FIG. 3A illustrates a device structure 100A according to some embodiments. The device structure 100A is similar to the device structure 10 shown in FIGS. 1 and 2, with like numbers referring to like elements. In the device structure 100A, the sidewall channel region 110A that is in the channel 50 adjacent the sidewall gate region 82 does not extend deeper into the drift layer 40 than the channel layer 50. For example, in some embodiments, the channel layer 50 may have a thickness of about 2 microns, and the sidewall channel region 110A may extend through the thickness of the channel layer, or to a depth of about 2 microns from the source layer 60. The lower boundary of the sidewall channel region 110A is positioned such that the sidewall gate region 82 and the sidewall channel region 110A extend to about the same depth in the structure.

In some embodiments, the sidewall channel region 110A has a doping concentration of about 1E17 cm-3 or greater, such as between about 1E17 cm-3 and 1E19 cm-3. In some embodiments, the sidewall channel region 110A has a doping concentration of between about 3E17 cm-3 and 5E18 cm-3. In some embodiments, the sidewall channel region 110A has a doping concentration of about 1E18 cm-3.

In some embodiments, the channel layer 50 has a doping concentration of between about 5E15 cm-3 and 1E17 cm-3. In some embodiments, the channel layer 50 has a doping concentration of about 5E16 cm-3 or less, such as between about 5E15 cm-3 and 5E16 cm-3. In some embodiments, the channel layer 50 has a doping concentration of about 1.5E16 cm-3.

In some embodiments, the sidewall channel region 110A has a doping concentration at least about 10 times greater than a doping concentration of the channel layer 50, and in some cases at least about 100 times greater.

FIG. 3B illustrates a device structure 100B according to some embodiments. The device structure 100B is similar to the device structure 100A shown in FIG. 3A, with like numbers referring to like elements. In the device structure 100B, the sidewall channel region 110A extends to a depth in the channel layer 50 that is shallower than the channel layer 50. For example, in some embodiments, the channel layer 50 may have a thickness of about 2 microns, and the sidewall channel region 110B may extend less than 2 microns into the depth of the channel layer, such as to a depth of about 0.1 to 2 microns from the source layer 60.

In the device structure 100B, the lower boundary of the sidewall channel region 110B is positioned such that the sidewall gate region 82 extends deeper into the structure than the sidewall channel region 110B.

FIG. 3C illustrates a device structure 100C according to some embodiments. The device structure 100C is similar to the device structure 100B shown in FIG. 3B, with like numbers referring to like elements. In the device structure 100C, the sidewall channel region 110A extends to a depth in the channel layer 50 that is even shallower than the channel layer 50. For example, in some embodiments, the channel layer 50 may have a thickness of about 2 microns, and the sidewall channel region 110B may extend less than 2 microns into the depth of the channel layer, such as to a depth of about 0.1 to 1 microns from the source layer 60.

In the device structure 100C, the lower boundary of the sidewall channel region 110C is positioned such that the sidewall gate region 82 extends deeper into the structure than the sidewall channel region 110C.

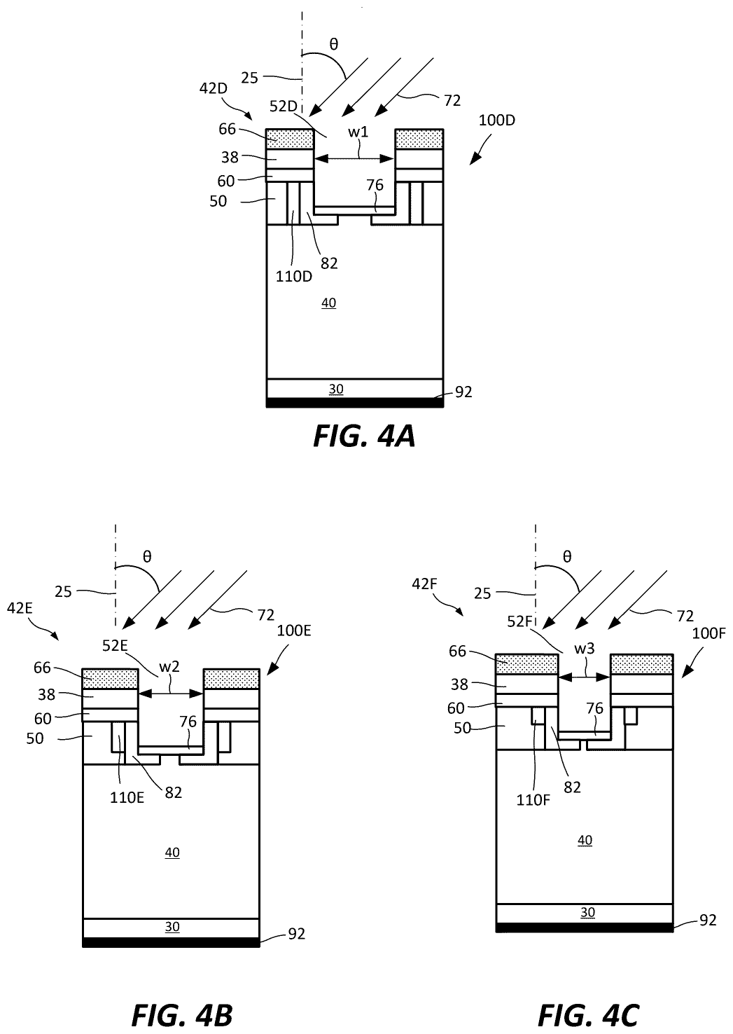

FIGS. 4A to 4C illustrate the effect of changing trench/mesa widths on the positioning of the lower boundary of the sidewall gate regions 110A, 110B, 110C, respectively. In particular, the device structure 100D shown in FIG. 4A has a trench width w1, the device structure 100E shown in FIG. 4B has a trench width w2 that is smaller than w1, and the device structure 100D shown in FIG. 4C has a trench width w3, that is smaller than w2. Assuming that all three device structures have the same width, this means that the mesa 42 of device structure 100D has a smaller width than the mesa 42 of device structure 100E, and that the mesa 42 of device structure 100E has a smaller width than the mesa 42 of device structure 100F. It will be appreciated that all of the device structures 100D, 100E and 100F may be formed on the same wafer, but may have different trench/mesa widths due to normal process variations.

The sidewall channel regions 110D, 110E and 110F are formed by the use of angled implantation of n-type dopant ions 72 at an implant angle θ. The same implantation process may produce sidewall implant regions 110D, 110E, and 110F having different depths due to shadowing caused by the mesas 42.

The aspect ratio of a trench 52 is equal to the depth of the trench divided by the width of the trench. Thus, a trench that has a large depth and narrow width has a larger aspect ratio than a trench that has a smaller depth and larger width. For example, for a given trench depth d, the device structure 100D shown in FIG. 4A has an aspect ratio of d/w1, while the device structure 100E shown in FIG. 4B has an aspect ratio of d/w2. Because w2<w1, the trench 52E of device structure 100E has a larger aspect ratio than the trench 52D of device structure 100D.

For a given implant angle θ, implants into a sidewall of a trench having a higher aspect ratio will be shadowed more than implants into a sidewall of a trench having a lower aspect ratio. This will result in the implanted region having a higher lower boundary, i.e., the implanted region will extend less deep into the implanted structure. Thus, for example, because the device 100E of FIG. 4B has a higher aspect ratio than the device 100D of FIG. 4A, the implants 72 used to form the sidewall channel region 110E of the device 100E will be partially shadowed by the mesa 42E and thus will not reach all the way to the bottom of the trench 52E. The sidewall channel region 110E will therefore extend a shorter distance beneath the source layer 60 than, for example, the sidewall channel region 110D of the device 100D of FIG. 4A which has a smaller aspect ratio and experiences less shadowing.

Similarly, because the device 100F of FIG. 4C has a higher aspect ratio than the device 100E of FIG. 4B, the implants 72 used to form the sidewall channel region 110F of the device 100F will be even more shadowed by the mesa 42F and thus will not reach all the way to the bottom of the trench 52F. The sidewall channel region 110F will therefore extend a shorter distance beneath the source layer 60 than, for example, the sidewall channel region 110E of the device 100E of FIG. 4B which has a smaller aspect ratio.

According to some embodiments, the mesa width, aspect ratio and implant angle θ are chosen to form the sidewall channel region 110E as shown in FIG. 4B such that it extends partially down the channel layer 50. Normal process variations may cause one or more mesas of the device to have slightly greater or smaller widths than the design width. If a given mesa width is slightly larger, the aspect ratio of a trench next to the mesa will be higher, causing more shadowing of the n-type implants 72 and resulting in the formation of a sidewall channel region 110F that extends less deeply into the channel layer 50 as shown in FIG. 4C. This may have the effect of increasing RDSON of the device somewhat but reducing DIBL.

Conversely, if a given mesa width is slightly smaller than the design width, the aspect ratio of a trench next to the mesa will be lower, causing less shadowing of the n-type implants 72 and resulting in the formation of a sidewall channel region 110D that extends more deeply into the channel layer 50 as shown in FIG. 4A. This may have the effect of decreasing RDSON of the device but increasing DIBL somewhat.

As an example, a typical silicon carbide JFET device may have a channel length of about 2 microns, with a mesa design width of 1.2 microns and a trench design width of 1.3 microns. Assuming that the mesa width can vary by +/−0.1 microns, the trench width will vary from about 1.2 microns to 1.4 microns. If the n+ sidewall implant is performed at an implant angle of 35 degrees in a trench having a width of 1.4 microns, the implants would just reach the bottom of the channel, because arctan(1.4/2) is about equal to 35 degrees. In the median case where the trench width is about 1.3 microns, a 35 degree tilted implant will only reach about 1.86 um (1.3/tan35) from the top of mesa due to shadowing. When the trench is about 1.2 microns, a 35 degree tilted implant will only reach about 1.71 microns (1.2/tan35) from the top of the mesa due to shadowing.

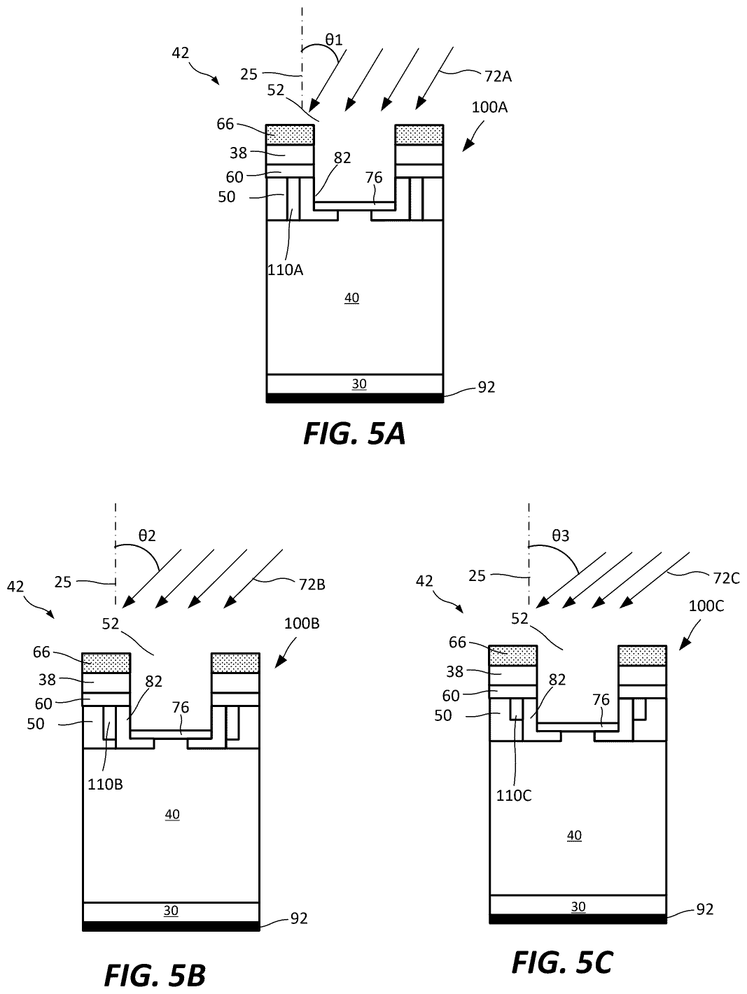

FIGS. 5A to 5C illustrate some operations for forming the sidewall channel regions of a device according to some embodiments. As described above, some embodiments place the lower boundary of the sidewall channel region 110 at a depth in the device that is less than the thickness of the channel layer 50 so that process variations in the mesa widths during manufacturing of the device may cause the lower boundary of the sidewall channel region 110 to move up or down as a result of implant shadowing. To place the lower boundary of the sidewall channel region 110 at a desired location, a different implant angle may be used to implant the sidewall channel regions 110 than is used to implant the p+ sidewall gate regions 82.

For example, FIG. 5A illustrates the implantation of n-type dopant ions 72 at a first implant angle θ1, FIG. 5B illustrates the implantation of n-type dopant ions 72 at a second implant angle θ2 that is greater than θ1, and FIG. 5C illustrates the implantation of n-type dopant ions 72 at a third implant angle θ3 that is greater than θ3. As seen in FIGS. 5A, 5B and 5C, a higher implant angle results in more shadowing of the implants and consequently a shallower depth of the sidewall channel region 110.

As the mesa width becomes smaller, the threshold voltage VT increases. Also, as the mesa width becomes smaller, the trench width increases and the trench aspect ratio becomes smaller. The n+ sidewall channel doping will not be shadowed as much and will reach a higher depth into the mesa closer to the drain. This has the effect of increasing the length of the more conductive channel and improving Rsp at the expense of some increase of DIBL.

Conversely, as the mesa width becomes larger, the threshold voltage VT reduces. As the mesa width increases, the trench width decreases and the trench aspect ratio increases. This causes the n+ sidewall channel doping to be more shadowed and to reach a smaller depth in the mesa so that the more highly doped sidewall channel region does not extend as close to the drain end of the channel. This reduces the length of more conductive portion of the sidewall channel region, which may improve DIBL at the expense of some increase of Rsp.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “in electrically conductive contact” means that two elements are in direct or indirect contact in such a way that electrical current can flow from one element to another. At least part of the connection between the two elements may be electrically resistive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A vertical semiconductor device, comprising:
a drift layer;
a mesa on the drift layer, and a trench adjacent to the mesa, wherein the mesa comprises a mesa sidewall, the mesa comprising a channel layer and a source layer on the channel layer, wherein the channel layer is between the source layer and the drift layer;
a sidewall gate region in the mesa adjacent the mesa sidewall; and
a sidewall channel region in the channel layer adjacent the sidewall gate region;
wherein the channel layer is doped with first conductivity type dopants and has a first doping concentration;
wherein the sidewall channel region is doped with first conductivity type dopants and has a second doping concentration that is greater than the first doping concentration;
wherein the sidewall gate region extends deeper toward the drift layer than the sidewall channel region.

2. The vertical semiconductor device of claim 1, wherein the sidewall channel region has a graded doping profile in a vertical direction.

3. The vertical semiconductor device of claim 2, wherein the sidewall channel region has a step graded doping profile.

4. The vertical semiconductor device of claim 2, wherein the sidewall channel region has a continuously graded doping profile.

5. The vertical semiconductor device of claim 1, wherein the channel layer has a first length in a vertical direction and wherein the sidewall channel layer has a second length in the vertical direction that is less than the first length.

6. The vertical semiconductor device of claim 1, wherein the first doping concentration is about 1E16 to 1E17 cm-3 and the second doping concentration is about 1E17 to 1E18 cm-3.

7. The vertical semiconductor device of claim 1, wherein the first doping concentration is less than about 1E17 cm-3 and the second doping concentration is greater than about 1E17 cm-3.

8. The vertical semiconductor device of claim 1, wherein the mesa has a width of about 1 micron to 1.5 microns and the trench has a width of about 1 micron to 1.5 microns.

9. The vertical semiconductor device of claim 1, wherein the mesa has a width of about 1.2 microns to 1.4 microns and the trench has a width of about 1.2 microns to 1.4 microns.

10. The vertical semiconductor device of claim 1, wherein the trench has an aspect ratio of about 1.5 to 2.

11. A method of forming a vertical semiconductor device, comprising:
forming a mesa in a semiconductor layer and a trench adjacent to the mesa, wherein the mesa comprises a mesa sidewall, the mesa comprising a channel layer and a source layer on the channel layer, wherein the semiconductor layer, the channel layer and the source layer have a first conductivity type;
implanting second conductivity type dopant ions into a sidewall of the mesa at a first implant angle to form a sidewall gate region in the mesa; and
implanting first conductivity type dopant ions into the sidewall of the mesa at a second implant angle to form a sidewall channel region in the channel layer adjacent to the sidewall gate region;
wherein the first implant angle is different from the second implant angle.

12. The method of claim 11, wherein the first implant angle is greater than the second implant angle, wherein the first and second implant angles are measured relative to a normal direction.

13. The method of claim 11, wherein the sidewall channel region has a smaller doping concentration in a lower region of the mesa and a larger doping concentration in an upper region of the mesa.

14. The method of claim 11, wherein the channel layer extends deeper in the mesa than the sidewall channel region.

15. The method of claim 11, wherein the sidewall gate region extends deeper in the mesa than the sidewall channel region.

16. The method of claim 11, wherein the sidewall channel region has a graded doping profile in a vertical direction.

17. The method of claim 16, wherein the sidewall channel region has a step graded doping profile.

18. The method of claim 16, wherein the sidewall channel region has a continuously graded doping profile.

19. The method of claim 11, wherein the first implant angle is less than 30 degrees and the second implant angle is greater than 30 degrees.

20. The method of claim 11, wherein the trench has an aspect ratio of about 1.5 to 2.

21. A vertical semiconductor device, comprising:
a drift layer;
a mesa on the drift layer, and a trench adjacent to the mesa, wherein the mesa comprises a mesa sidewall, the mesa comprising a channel layer and a source layer on the channel layer; and
a sidewall channel region in the channel layer, wherein the sidewall channel region is doped with first conductivity type dopants and has a first doping concentration, wherein the sidewall channel region has a smaller doping concentration in a lower region near the drift layer and a larger doping concentration in an upper region away from the drift layer.

22. The vertical semiconductor device of claim 21, wherein the sidewall channel region has a graded doping profile in a vertical direction from the upper region to the lower region.

23. The vertical semiconductor device of claim 22, wherein the sidewall channel region has a step graded doping profile in the vertical direction.

24. The vertical semiconductor device of claim 22, wherein the sidewall channel region has a continuously graded doping profile in the vertical direction.

25. The vertical semiconductor device of claim 21, wherein the channel layer has a first length in a vertical direction and wherein the sidewall channel region has a second length in the vertical direction that is less than the first length.

26. The vertical semiconductor device of claim 21, further comprising a sidewall gate region adjacent the sidewall channel region, wherein the sidewall gate region extends deeper into the drift layer than the sidewall channel region.

27. A vertical semiconductor device, comprising:
a drift layer, wherein the drift layer is doped with dopant atoms having a first conductivity type at a first doping concentration;
a mesa on the drift layer, and a trench adjacent to the mesa, wherein the mesa comprises a mesa sidewall, the mesa comprising a channel layer and a source layer on the channel layer, wherein the channel layer is between the source layer and the drift layer;
a sidewall gate region in the mesa adjacent the mesa sidewall; and
a sidewall channel region in the channel layer adjacent the sidewall gate region;
wherein the sidewall channel region is doped with first conductivity type dopants and has a second doping concentration that is greater than the first doping concentration;
wherein the sidewall channel region has a smaller doping concentration in a lower region near the drift layer and a larger doping concentration in an upper region away from the drift layer.

28. The vertical semiconductor device of claim 27, wherein the sidewall channel region has a graded doping profile in a vertical direction from the upper region to the lower region.

29. The vertical semiconductor device of claim 28, wherein the sidewall channel region has a step graded doping profile in the vertical direction.

30. The vertical semiconductor device of claim 28, wherein the sidewall channel region has a continuously graded doping profile in the vertical direction.

31. The vertical semiconductor device of claim 27, wherein the channel layer has a first length in a vertical direction and wherein the sidewall channel layer has a second length in the vertical direction that is less than the first length.

32. The vertical semiconductor device of claim 27, wherein the sidewall gate region extends deeper into the drift layer than the sidewall channel region.

33. A method of forming a vertical semiconductor device, comprising:
forming a plurality of mesas in a semiconductor layer and a plurality of trenches adjacent to respective ones of the mesas, wherein each of the plurality of mesas comprises a mesa sidewall, a channel layer and a source layer on the channel layer, wherein the semiconductor layer, the channel layer and the source layer have a first conductivity type; and
implanting first conductivity type dopant ions into the sidewalls of the mesas at an implant angle to form sidewall channel regions in the channel layer;
wherein a first sidewall channel region extends to a first depth in a first one of the mesas that is less than a depth of the channel layer; and
wherein a second one of the mesas has a different width than the first one of the mesas due to a process variation, and a second sidewall channel region extends to a second depth in the second one of the mesas that is different from the first depth.

34. The method of claim 33, wherein the implant angle comprises a first implant angle, the method further comprising:
implanting second conductivity type dopant ions into the sidewalls of the mesa at a second implant angle that is less than the first implant angle to form the sidewall gate regions in the mesas.

35. The method of claim 34, wherein the sidewall gate regions extend deeper in the mesa than the first sidewall channel region.

36. The method of claim 33, wherein the sidewall channel region has a smaller doping concentration in a lower region of the mesa and a larger doping concentration in an upper region of the mesa.

37. The method of claim 33, wherein the channel layer extends deeper in the mesa than the sidewall channel regions.

38. The method of claim 33, wherein the sidewall channel regions have a graded doping profile in a vertical direction.

39. The method of claim 38, wherein the sidewall channel regions have a step graded doping profile.

40. The method of claim 38, wherein the sidewall channel regions have a continuously graded doping profile.
